(19) United States
(12) Patent Application Publication
(10) Pub. No.: US 2025/0317046 A1
(43) Pub. Date: Oct. 9, 2025

(54) CIRCUITRY SYSTEM AND METHOD FOR REGULATING VOLTAGE THEREOF USING DYNAMIC DECOUPLING CAPACITOR

(71) Applicant: SKYECHIP SDN BHD, BAYAN LEPAS (MY)

(72) Inventors: Wilfred Wee Kee KING, BAYAN LEPAS (MY); Tat Hin TAN, BAYAN LEPAS (MY); Selvakumar SIVARAJAH, BAYAN LEPAS (MY); Jaw Wen CHEW, BAYAN LEPAS (MY)

(73) Assignee: SKYECHIP SDN BHD, BAYAN LEPAS (MY)

(21) Appl. No.: 18/737,958

(22) Filed: Jun. 8, 2024

(30) Foreign Application Priority Data
Apr. 3, 2024 (MY) PI2024002016

(51) Int. Cl. H02M 1/088; H02M 1/14; H02M 3/07

(52) U.S. Cl. CPC H02M 1/088; H02M 1/143; H02M 3/07

(57) ABSTRACT

The present invention relates to a circuitry system (1). The circuitry system (1) comprises a reservoir power rail (12), a regulated power rail (14), a logic circuitry (18) connected to the regulated power rail (14), wherein each of the reservoir power rail (12), regulated power rail (14) and logic circuitry (18) is connected to respective voltage supply source (16), characterized by a dynamic decoupling capacitor (10) connecting the reservoir power rail (12) to the regulated power rail (14), and in communication with the logic circuitry (18), wherein the dynamic decoupling capacitor (10) is configured to match a total-charge of injected-current, l_{decap}, from the reservoir power rail (12) with a total-charge of load-current, l_{load}, supplying to the logic circuitry (18). A method for regulating voltage of the circuitry system (1) is also disclosed herein.

### TECHNICAL FIELD

The present invention relates generally to regulation of voltage in a circuit. More particularly, it relates to a circuitry system and a method for regulating voltage in the circuitry system using a dynamic decoupling capacitor.

### BACKGROUND ART

A complementary metal oxide semiconductor (CMOS) circuit is a high-speed logic circuit widely used in today's integrated circuits. However, its burst-idle-burst activity characteristics can lead to significant voltage droop and overshoot in a power rail. Consequently, results in an additional timing loss during the recovery from power supply-induced jitter.

One approach to mitigate voltage droop and overshoot in the power rail is to employ a decoupling capacitor. A decoupling capacitor provides a bypass path for transient currents instead of flowing through the common impedance. The decoupling capacitor works as local energy storage. However, the conventional decoupling capacitors are passive capacitors that are constrained by the voltage droop requirement on a specific current. Therefore, the conventional approach comes with several drawbacks. For instance, the use of a large amount of on-die decoupling capacitor consumes considerable space and introduces instability issues for the regulated power rail. Additionally, the use of analog-based active-decoupling capacitor or decoupling capacitor-multiplier does not provide a high-speed reaction. Furthermore, separating the power rail for burst-idle-burst components requires additional power rail routing resources. This approach does not address the timing loss of the component itself and may necessitate a level-shifter or an isolation-cell in the high-speed path.

A prior art example which attempts to solve the same problem is provided below:

United States patent U.S. Pat. No. 10,972,083B2 discloses a method for utilizing on-chip decoupling capacitors within a power distribution network to mitigate transient voltage drops on power supply lines of a power distribution network. The method comprising the steps of capacitively decoupling a power supply line of a power distribution network using a first decoupling capacitor which is connected to the power supply line and charged to a first voltage level of the power supply line, to mitigate voltage droop on the power supply line when the first voltage level does not decrease to a level which is at or below a droop threshold voltage level, pre-charging a second decoupling capacitor to a second voltage level which is greater than the first voltage level, determining an occurrence of a droop event in which the first voltage level decreases to a level which is at or below a droop threshold voltage level, and selectively connecting the pre-charged second decoupling capacitor to the power supply line in response to determining the occurrence of the droop event, to thereby apply the second voltage level to the power supply line and source boosting current to the power supply line through discharging of the second decoupling capacitor. The prior art requires additional components, such as a voltage booster circuit, a higher voltage power rail or negative power supply line, and a droop prediction and detection circuit. These additions may lead to elevated cost, increased complexity, and higher power consumption. Additionally, the prior art is implemented at the functional circuit block level, lacking visibility into the internal activities of the block. Consequently, the addition of droop prediction and detection circuit becomes imperative in this context.

Hence, there remains a need to provide a circuitry system and a method capable of addressing the aforementioned problems and shortcomings. The present invention provides a streamlined circuitry system with a dynamic decoupling capacitor and a method that exhibits high-speed responsiveness and scalability with logic circuitries in voltage regulation, wherein the circuitry system occupies a smaller area within the functional block of logic and involves reduced number of power rails for effective voltage regulation. Moreover, the present invention is implemented at the gate or cell level. This allows direct access to the internal activity signals of the block, eliminating the need for a droop prediction and detection circuit.

### SUMMARY OF THE INVENTION

The following presents a simplified summary of the invention in order to provide a basic understanding of some aspects of the invention. This summary is not an extensive overview of the invention. Its sole purpose is to present some concepts of the invention in a simplified form as a prelude to the more detailed description that is presented later.

It is an objective of the present invention to provide a circuitry system with a dynamic decoupling capacitor that can be implemented at gate or cell level for voltage regulation.

It is also an objective of the present invention to provide a circuitry system with a dynamic decoupling capacitor that is scalable with the circuitry in voltage regulation.

It is yet another objective of the present invention to provide a streamlined circuitry system with a dynamic decoupling capacitor that occupies a smaller area of functional block of logic in voltage regulation.

It is further an objective of the present invention to provide a method for regulating voltage in a circuitry that can address the recovery of power supply-induced jitter timing loss caused by burst-idle-burst activity.

Accordingly, these objectives may be achieved by following the teachings of the present invention. The present invention relates to a circuitry system. The circuitry system comprising a reservoir power rail, a regulated power rail, a logic circuitry connected to the regulated power rail, wherein each of the reservoir power rail, regulated power rail and logic circuitry is connected to respective voltage supply source, characterized by a dynamic decoupling capacitor connecting the reservoir power rail to the regulated power rail, and in communication with the logic circuitry, wherein the dynamic decoupling capacitor is configured to match a total-charge of injected-current, l_{decap}, from the reservoir power rail with a total-charge of load-current, l_{load}, supplying to the logic circuitry.

The present invention further relates to a method for regulating voltage in a circuitry system using a dynamic decoupling capacitor. The method comprising the steps of detecting an incoming switching in logic circuitry, charging the dynamic decoupling capacitor from the reservoir power rail and discharging a primary load of a logic circuitry, and discharging the dynamic decoupling capacitor to zero and simultaneously charging the logic circuitry, wherein the load-current's charge-of-l_{load} is identical to the charge-of-l_{decap}, wherein the charge-of-l_{load} and charge-of-l_{decap} refer to the integration of respective currents over time.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

So that the manner in which the above recited features of the present invention can be understood in detail, a more particular description of the invention, briefly summarized above, may have been referred by embodiments, some of which are illustrated in the appended drawings. It is to be noted, however, that the appended drawings illustrate only typical embodiments of this invention and are therefore not to be considered limiting of its scope, for the invention may admit to other equally effective embodiments.

These and other features, benefits, and advantages of the present invention will become apparent by reference to the following text figures, with like reference numbers referring to like structures across the views, wherein:

FIG. 1 is a diagram illustrating a circuitry system with an implementation of a dynamic decoupling capacitor in accordance with an embodiment of the present invention;

FIG. 2A is a diagram illustrating a charging phase of a dynamic decoupling capacitor in accordance with an embodiment of the present invention;

FIG. 2B is a diagram illustrating a discharging phase of a dynamic decoupling capacitor in accordance with an embodiment of the present invention;

FIG. 3 is an example illustrating an implementation of two dynamic decoupling capacitors for voltage regulation in a circuitry system; and

FIG. 4 is a diagram illustrating simulation results of two setups: (a) without a dynamic decoupling capacitor and (b) with a dynamic decoupling capacitor.

### DETAILED DESCRIPTION OF THE INVENTION

As required, detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting but merely as a basis for claims. It should be understood that the drawings and detailed description thereto are not intended to limit the invention to the particular form disclosed, but on the contrary, the invention is to cover all modifications, equivalents and alternatives falling within the scope of the present invention as defined by the appended claims. As used throughout this application, the word “may” is used in a permissive sense (i.e., meaning having the potential to), rather than the mandatory sense (i.e., meaning must). Similarly, the words “include,” “including,” and “includes” mean including, but not limited to. Further, the words “a” or “an” mean “at least one” and the word “plurality” means one or more, unless otherwise mentioned. Where the abbreviations or technical terms are used, these indicate the commonly accepted meanings as known in the technical field.

The present invention is described hereinafter by various embodiments with reference to the accompanying drawings, wherein reference numerals used in the accompanying drawings correspond to the like elements throughout the description. This invention may, however, be embodied in many different forms and should not be construed as limited to the embodiment set forth herein. Rather, the embodiment is provided so that this disclosure will be thorough and complete and will fully convey the scope of the invention to those skilled in the art. In the following detailed description, numeric values and ranges are provided for various aspects of the implementations described. These values and ranges are to be treated as examples only, and are not intended to limit the scope of the claims. In addition, a number of materials are identified as suitable for various facets of the implementations. These materials are to be treated as exemplary, and are not intended to limit the scope of the invention.

The present invention relates to a circuitry system (1) and a method for regulating voltage in the circuitry system (1) by integrating a dynamic decoupling capacitor (10), particularly addressing the challenges posed by a high-speed logic circuit with burst-idle-burst activity characteristics, which may cause significant voltage droop and overshoot in a power supply rail.

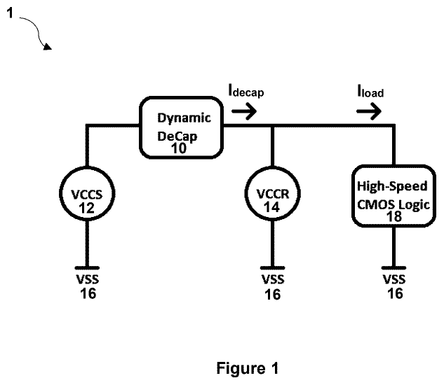

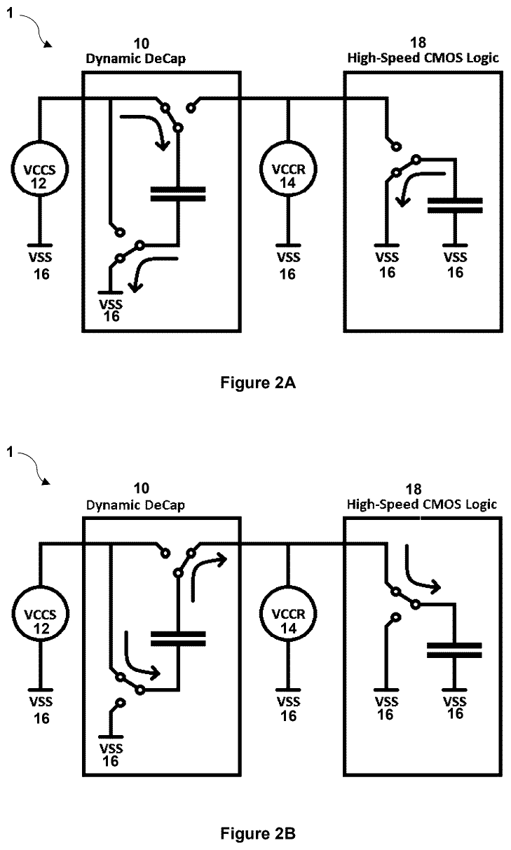

Referring to FIGS. 1 to 2, the invention will now be described in more details. The figures only illustrate a single loading to ground within the circuit. It is understandable by a skilled person in the art that in actual implementation, the circuit is not limited to single loading to ground, it can be very complex, the current can be drawn from both rising and falling edges of the signal transitions and the current consumed at those edges can be different from one another.

FIG. 1 is a flow diagram illustrating the circuitry system (1) in accordance with an embodiment of the present invention. The circuitry system (1) comprising a reservoir power rail (12), a regulated power rail (14), a logic circuitry (18) connected to the regulated power rail (14), wherein each of the reservoir power rail (12), regulated power rail (14) and logic circuitry (18) is connected to respective voltage supply source (16), characterized by the dynamic decoupling capacitor (10) connecting the reservoir power rail (12) to the regulated power rail (14), and in communication with the logic circuitry (18), wherein the dynamic decoupling capacitor (10) is configured to match a total-charge of injected-current, l_{decap}, from the reservoir power rail (12) with a total-charge of load-current, l_{load}, supplying to the logic circuitry (18). More specifically, l_{decap} is a current introduced by the dynamic decoupling capacitor (10) from the reservoir power rail (12), and l_{load} is a current drawn by a primary load of the logic circuitry (18).

In accordance with an embodiment of the present invention, the dynamic decoupling capacitor (10) comprises a charge-pump based architecture to facilitate the transfer of charge to or from the dynamic decoupling capacitor (10), enabling voltage transformation and regulation within the circuitry system (1).

In accordance with an embodiment of the present invention, the dynamic decoupling capacitor (10) is scalable with the logic circuitry (18). As the present invention targets gate or cell level, the gates or cells can be pre-built with built-in dynamic decoupling capacitor (10) for constructing the block. Consequently, the dynamic decoupling capacitor (10) scales directly with the size of the block since it is integrated into the block's building gates or cells. In other words, the dynamic decoupling capacitor (10) is able to adjust capacitance value in relation to the requirements of the logic circuitry (18), providing flexibility, adaptability, and optimization in the circuit design process.

In accordance with an embodiment of the present invention, the logic circuitry (18) is a CMOS logic circuitry.

In accordance with an embodiment of the present invention, the method for regulating voltage in the circuitry system (1) by the dynamic decoupling capacitor (10) comprising the steps of detecting an incoming switching in logic circuitry (18), charging the dynamic decoupling capacitor (10) from the reservoir power rail (12) and discharging the primary load of the logic circuitry (18) simultaneously, and discharging the dynamic decoupling capacitor (10) to zero and simultaneously charging the logic circuitry (18), wherein the load current's charge-of-l_{load} is identical to the charge-of-l_{decap}, wherein the charge-of-l_{load} and charge-of-l_{decap} refer to the integration of respective currents over time.

In accordance with an embodiment of the present invention, the dynamic decoupling capacitor (10) is charged from a reservoir voltage supply source (16), which is separated from the regulated supply source.

As mentioned above, the dynamic decoupling capacitor (10) comprises two operational phases, which are a charging phase and a discharging phase. The charging and discharging of the dynamic decoupling capacitor (10) are dynamic processes that occur based on the varying current demand of the logic circuitry (18).

FIG. 2A is a diagram illustrating the charging phase of the dynamic decoupling capacitor (10) in accordance with an embodiment of the present invention. The charging phase occurs during the idle phase (low or no activity) or when the demand for current is reduced in the logic circuitry (18). During the charging phase, there is no current required from the regulated power rail (14) and the logic circuity (18). Consequently, the logic circuity (18) discharges its primary load. This creates a window for the reservoir power rail (12) to charge up the dynamic decoupling capacitor (10) for later use during the discharging phase.

FIG. 2B is a diagram illustrating the discharging phase of the dynamic decoupling capacitor (10) in accordance with an embodiment of the present invention. The discharging phase occurs during the burst phase (high activity) or when there is a high demand for current in the logic circuitry (18). During the discharge phase, the current will be drained from the regulated power rail (14) to the logic circuitry (18) for charging the primary load. To maintain the current stability and minimize the voltage drooping of the regulated power rail (14), the stored charge in the dynamic decoupling capacitor (10) will be discharged to supply the required current to the regulated power rail (14) when the logic circuitry (18) demands current from the regulated power rail (14). Notable, the amount of charget discharged from the dynamic decoupling capacitor (10) is same as the amount of charge demanded by the logic circuitry (18). When the injected charge into the logic circuitry (18) equals the discharged charge from the dynamic decoupling capacitor (10) and both processes occur simultaneously, the voltage of the regulated power rail (14) will experience zero droop.

In accordance with an embodiment of the present invention, in a setup where reservoir power rail (12) and regulated power rail (14) have the same voltage, if the capacitance value is the same for the reservoir power rail (12) and the regulated power rail (14), the charge being stored in the dynamic decoupling capacitor (10) will be the same as the charge being drained from a capacitor of the logic circuit (18). In other words, for the devices where the dynamic decoupling capacitor (10) is also used as the capacitor of the logic circuit (18) and have the reservoir power rail (12) to track the regulated power rail (14), the l_{decap} will be able to track the l_{load} across the process, and wide variety of voltage and temperature.

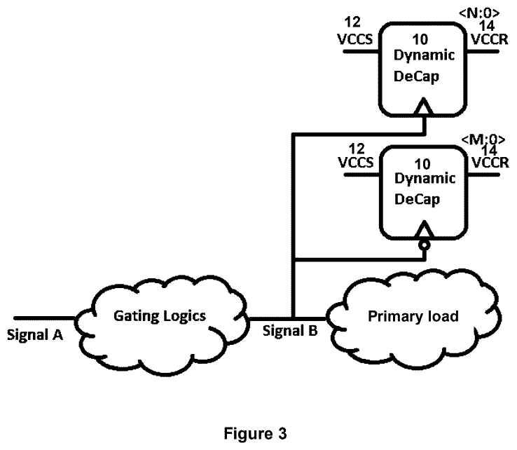

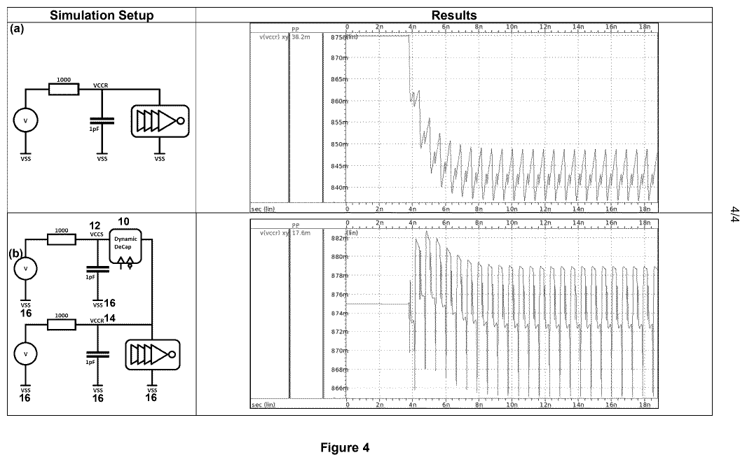

Hereinafter, an example of the present invention will be provided for more detailed explanation by referring to FIGS. 3 to 4. The advantages of the present invention may be more readily understood and put into practical effect from this example. However, it is to be understood that the following example is not intended to limit the scope of the present invention in any ways.

### EXAMPLES

FIG. 3 is a diagram illustrating an implementation of two dynamic decoupling capacitors (10) for regulating voltage in a circuitry. In this implementation, current is drawn from both rising and falling edges of the signal transitions. One of the dynamic decoupling capacitors (10) is triggered by the positive-edge of Signal B, while another dynamic decoupling capacitor (10) is triggered by the negative-edge of Signal B. This configuration allows the dynamic decoupling capacitors (10) to match the positive-edge current consumption and negative-edge current consumption of the load capacitor accurately by adjusting the array size of <N: 0>and <M: 0>. Additionally, signal B which exhibits the highest correlation with the loading current is selected as the trigger for the dynamic decoupling capacitor (10) instead of signal A. This is because signal B can be gated-off from Signal A dynamically under specific logic conditions. This configuration of the dynamic decoupling capacitor (10) is highly effective in mitigating sudden voltage droop in the regulated power rail (14) caused by the burst-idle-burst characteristic of Signal B. This is achieved by shifting all or most of the burst-idle-burst current profile from the regulated power rail (14) to the reservoir power rail (12).

FIG. 4 is a diagram illustrating the simulation results of two setups, (a) depicts a configuration without the dynamic decoupling capacitor (10), and (b) depicts a configuration with the dynamic decoupling capacitor (10). The simulation was conducted using an idle-burst stimulus. According to the simulation results, the setup without the dynamic decoupling capacitor (10) exhibited voltage fluctuations at the regulated power rail (14), whereas the setup with the dynamic decoupling capacitor (10) exhibited stable voltage with no fluctuations at the regulated power rail (14).

The system (10) and method of the present invention effectively address the problems and shortcomings of the existing solutions. For example, the present invention can mitigate voltage fluctuations to produce a more stable power rail and minimize power supply-induced jitter timing loss. This capability enables a specific system to operate at a higher data rate. Additionally, the present invention provides a more streamlined circuitry system (1) with the dynamic decoupling capacitor (10) that can achieve smaller area of functional block of logic in voltage regulation. Moreover, the dynamic decoupling capacitor (10) is an active capacitor that is not constrained by the voltage droop requirement on a specific current like conventional passive decoupling capacitors.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is to be providing broadest scope of consistent with the principles and the novel and inventive features disclosed or suggested herein. Accordingly, the invention is anticipated to hold on to all other such alternatives, modifications, and variations that fall within the scope of the present invention and appended claim.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1. A circuitry system (1), comprising:
a reservoir power rail (12);
a regulated power rail (14);
a logic circuitry (18) connected to the regulated power rail (14);
wherein each of the reservoir power rail (12), regulated power rail (14) and logic circuitry (18) is connected to respective voltage supply source (16);
characterized by a dynamic decoupling capacitor (10) connecting the reservoir power rail (12) to the regulated power rail (14), and in communication with the logic circuitry (18);
wherein the dynamic decoupling capacitor (10) is configured to match a total-charge of injected-current, l_{decap}, from the reservoir power rail (12) with a total-charge of load-current, l_{load}, supplying to the logic circuitry (18).

2. The circuitry system (1) as claimed in claim 1, wherein the dynamic decoupling capacitor (10) comprises a charge-pump based architecture.

3. The circuitry system (1) as claimed in claim 1, wherein the dynamic decoupling capacitor (10) is scalable with the logic circuitry (18).

4. The circuitry system (1) as claimed in claim 1, wherein the logic circuitry (18) is a complementary metal oxide semiconductor logic circuitry.

5. A method for regulating voltage in a circuitry system (1) using a dynamic decoupling capacitor (10) as claimed in claim 1, the method comprising the steps of:
detecting an incoming switching in logic circuitry (18);
charging the dynamic decoupling capacitor (10) from the reservoir power rail (12) and discharging the primary load of a logic circuitry (18); and
discharging the dynamic decoupling capacitor (10) to zero and simultaneously charging the logic circuitry (18);
wherein the load-current's charge-of-l_{load} is identical to the charge-of-l_{decap};
wherein the charge-of-l_{load} and charge-of-l_{decap} refer to the integration of respective currents over time.

6. The method as claimed in claim 5, wherein charging the dynamic decoupling capacitor (10) from a reservoir voltage supply source (16), which is separated from the regulated supply source (14).
